(19) United States
(12) Patent Application Publication
(10) Pub. No.: US 2013/0140062 A1
(43) Pub. Date: Jun. 6, 2013

(54) CIRCUIT BOARD STRUCTURE AND METHOD FOR MANUFACTURING THE SAME

(71) Applicants: Kuang-Yao Chang, Shenzhen (CN); Lin-Dong Fang, Shenzhen (CN)

(72) Inventors: Kuang-Yao Chang, Shenzhen (CN); Lin-Dong Fang, Shenzhen (CN)

(21) Appl. No.: 13/497,467

(22) PCT Filed: Jan. 4, 2012
(86) PCT No.: PCT/CN12/70018

§ 371 Date: Mar. 21, 2012

(30) Foreign Application Priority Data
Dec. 5, 2011 (CN) 201110399203.9

(51) Int. Cl. H05K 1/05; H05K 3/00

(52) U.S. Cl. 174/255; 29/846

(57) ABSTRACT

A manufacturing method of a circuit board structure includes steps of: providing a circuit board which comprising a metal substrate, a metal layer and a dielectric layer disposed between the metal substrate and the metal layer; forming grooves on the circuit board to expose the metal substrate, the dielectric layer and the metal layer; performing a procedure for connecting metal in the grooves so that the metal substrate and the metal layer being in contact with each other. A structure of circuit board comprises a metal substrate, a dielectric layer and a metal layer. The dielectric layer is formed on the metal substrate, and the metal layer is formed on the dielectric layer; wherein the metal substrate and the metal layer can be in contact with each other at an appropriate position by performing a metal connecting procedure.

### FIELD OF THE INVENTION

The present invention relates to a manufacturing technique of circuit board and more particularly to a circuit board structure and method for manufacturing the same.

### BACKGROUND OF THE INVENTION

Referring to FIG. 1, which is an illustration of a conventional metal core printed circuit board.

As shown in FIG. 1, a conventional metal core printed circuit board (MCPCB) 1 comprises a metal substrate 10, a dielectric layer 11 and a metal layer 12. The dielectric layer 11 is formed between the metal substrate 10 and the metal layer 12 as an insulation layer, the metal substrate 10 can be an aluminum substrate and the metal layer 12 can be a copper layer.

However, it can be known from the structure of the metal core printed circuit board 1, because the dielectric layer 11 is nonconductive, the metal layer 12 and the metal substrate 10 are not in contact with each other. Furthermore, a heat conduction coefficient (2-4.7 W/m·k) of the dielectric layer 11 is a lot lower than a heat conduction coefficient (e.g. copper layer 398/401 W/m·k) of the metal layer 12 and a heat conduction coefficient (e.g. aluminum substrate 237 W/m·k) of the metal substrate 10, therefore the dielectric layer 11 is a bottleneck for heat dissipation of the metal core printed circuit board 1.

More specifically, when electronic components are disposed on a metal circuit of the metal layer 12, heat energy is generated after the electronic components are supplied with electricity; heat energy is generated on the metal layer 12 directly. And then the heat energy is transferred downward through the metal layer 12. However, because of an obstruction of the dielectric layer 11 with a lower heat conduction coefficient, the heat energy can not be transferred smoothly to the metal substrate 10.

Referring to FIG. 2, which is an illustration of the metal core printed circuit board in FIG. 1 with an electronic component.

As the mentioned above, when an electronic component (e.g. a light emitting diode module 13) is installed on the metal circuit of the metal layer 12 by surface mount technology (SMT), and heat energy H is generated when the light emitting diode module 13 is electrically connected and irradiates, therefore the heat energy H is generated on the metal layer 12 directly, then the heat energy H is transferred downward through the metal layer 12. However, because of an obstruction of the dielectric layer 11 with a lower heat conduction coefficient, the heat energy H can not be transferred smoothly to the metal substrate 10.

### SUMMARY

In order to solve the abovementioned conventional technical problems, the present invention provides a circuit board structure and method for manufacturing the same, by which a heat conduction coefficient and a heat dissipation efficiency of a circuit board can be enhanced.

A technical solution employed by the present invention to achieve the abovementioned objects includes providing a manufacturing method of a circuit board structure including steps of: providing a circuit board which comprising a metal substrate, a metal layer and a dielectric layer disposed between the metal substrate and the metal layer; forming grooves on the circuit board to expose the metal substrate, the dielectric layer and the metal layer; performing a procedure for connecting metal in the grooves so that the metal substrate and the metal layer being in contact with each other.

The manufacturing method of the present invention further including:

performing a procedure of exposure and etching on a surface of the metal layer to form a metal circuit on the surface;

forming an opening on an electronic component installation area of the metal circuit for connecting the metal substrate; and

installing a light emitting diode module on the electronic component installation area by surface mount technology (SMT), wherein a heat dissipation element of the light emitting diode module is in contact with the metal substrate through the opening.

A technical solution employed by the present invention to achieve the abovementioned objects includes providing a circuit board structure which comprises a metal substrate, a dielectric layer and a metal layer. The dielectric layer is formed on the metal substrate, and the metal layer is formed on the dielectric layer. The metal substrate and the metal layer can be in contact with each other at an appropriate position by performing a metal connecting procedure.

The circuit board structure of the present invention further comprises:

a metal circuit is disposed on a surface of the metal layer, an electronic component installation area of the metal circuit has an opening for connecting to the metal substrate;

a light emitting diode module is installed on the electronic component installation area, and a heat dissipation element of the light emitting diode module is in contact with the metal substrate through the opening;

a connector is further disposed on the surface of the metal layer to be electrically connected with the metal circuit;

the metal substrate includes an aluminum substrate; and

the metal layer includes a copper layer.

Compared with the conventional techniques and according to the circuit board structure and method for manufacturing the same, by having the metal substrate and the metal layer in contact with each other at an appropriate position, therefore a heat conduction coefficient and a heat dissipation efficiency of the circuit board can be enhanced.

### BRIEF DESCRIPTION OF THE DRAWINGS

FIG. 1 is an illustration of a conventional metal core printed circuit board;

FIG. 2 is an illustration of the conventional metal core printed circuit board in FIG. 1 with an electronic component;

FIG. 3 is a flow chart of a manufacturing method of a circuit board structure according to an embodiment of the present invention;

FIG. 4 is a first illustration of the manufacturing method of the circuit board structure according to an embodiment of the present invention;

FIG. 5 is a second illustration of the manufacturing method of the circuit board structure according to an embodiment of the present invention;

FIG. 6 is a third illustration of the manufacturing method of the circuit board structure according to an embodiment of the present invention;

FIG. 7 is a fourth illustration of the manufacturing method of the circuit board structure according to an embodiment of the present invention;

FIG. 8 is a perspective view of the circuit board structure according to an embodiment of the present invention; and

FIG. 9 is an illustration of the manufacturing method of the circuit board structure in FIG. 6 according to another embodiment of the present invention.

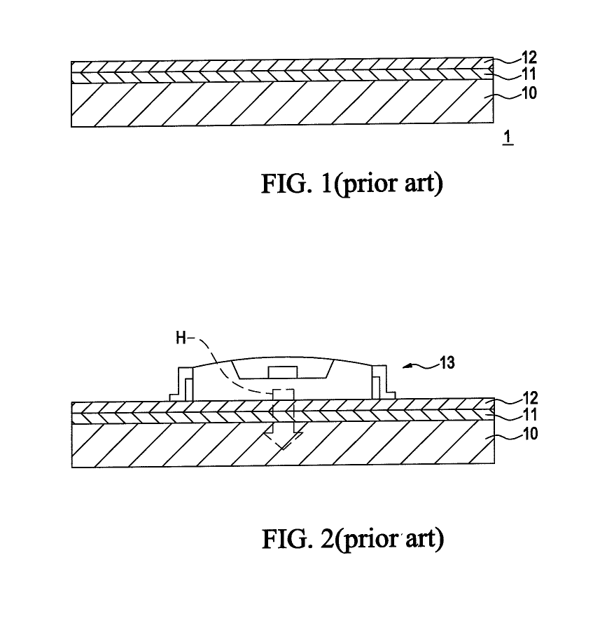

### DETAILED DESCRIPTION OF THE INVENTION

The present invention will become more fully understood by reference to the following detailed description thereof when read in conjunction with the attached drawings.

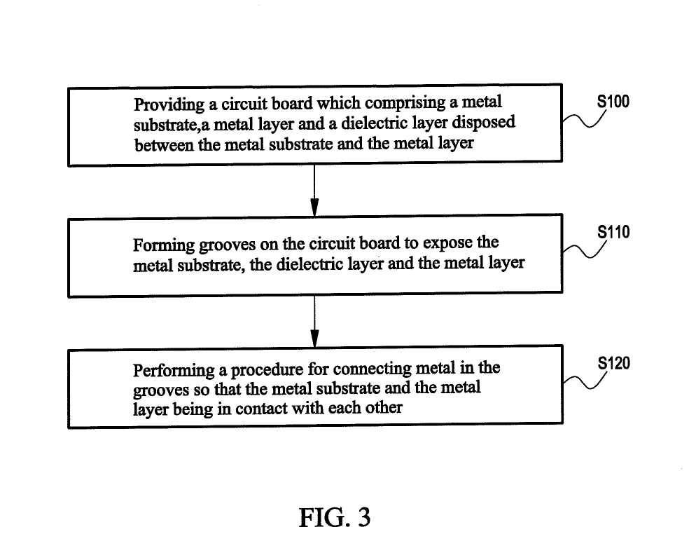

Referring to FIG. 3, which is a flow chart of a manufacturing method of a circuit board structure according to an embodiment of the present invention.

As shown in FIG. 3, the manufacturing method of the circuit board structure including steps of: (step S100) providing a circuit board which comprising a metal substrate, a metal layer and a dielectric layer disposed between the metal substrate and the metal layer; (step S110) forming grooves on the circuit board to expose the metal substrate, the dielectric layer and the metal layer; (step S120) performing a procedure for connecting metal in the grooves so that the metal substrate and the metal layer being in contact with each other.

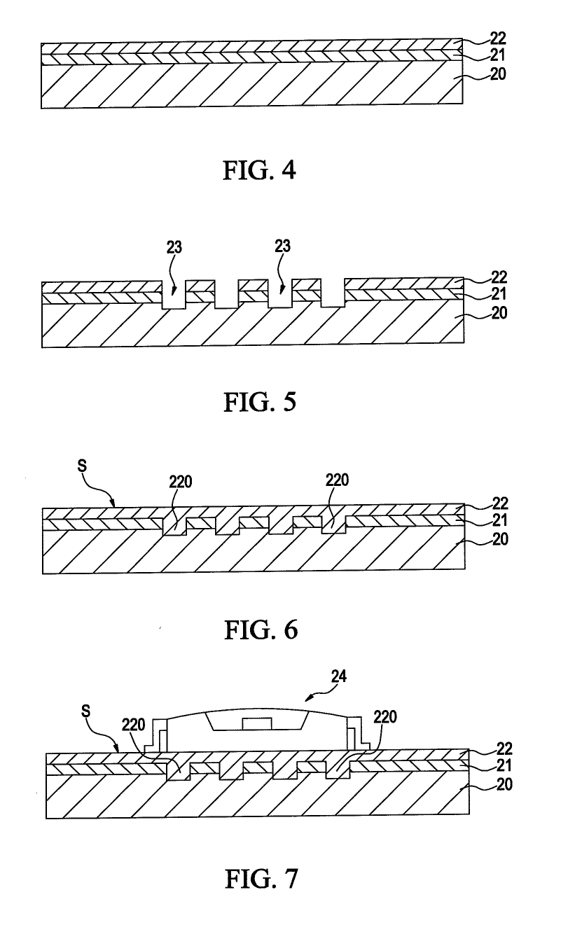

For detailed descriptions please refer to FIGS. 3, 4, 5 and 6. FIG. 4 is a first illustration of the manufacturing method of the circuit board structure according to an embodiment of the present invention; FIG. 5 is a second illustration of the manufacturing method of the circuit board structure according to an embodiment of the present invention; and FIG. 6 is a third illustration of the manufacturing method of the circuit board structure according to an embodiment of the present invention.

As shown in FIGS. 3 and 4, in the (step S100) of providing a circuit board which comprises a metal substrate, a metal layer and a dielectric layer disposed between the metal substrate and the metal layer, a bonding process can be employed so that the circuit board can have a multi-layered structure. The circuit board can be a metal core printed circuit board, and the circuit board comprises a metal substrate 20, a dielectric layer 21 and a metal layer 22. The dielectric layer 21 is formed between the metal substrate 20 and the metal layer 22 as an insulation layer.

As shown in FIGS. 3 and 5, in the (step S110) of forming grooves on the circuit board to expose the metal substrate, the dielectric layer and the metal layer, a process of drilling blind holes can be employed to form one or a plurality of grooves 23 on the circuit board to expose the metal substrate 20, the dielectric layer 21 and the metal layer 22 at positions of the grooves 23.

As shown in FIGS. 3 and 6, in the (step S120) of performing a procedure for connecting metal in the grooves so that the metal substrate and the metal layer are in contact with each other, a metal connecting procedure such as plating of a metal 220 (e.g. copper plating) can be performed in the grooves 23 so that the metal substrate 20 and the metal layer 22 are in contact with each other, therefore a heat conduction coefficient and an overall heat dissipation efficiency of the circuit board can be enhanced. In the embodiment, the grooves 23 are filled completely with the metal 220 so that the metal substrate 20 and the metal layer 22 can be in contact with each other. Furthermore, silver can also be used in the connecting procedure and a material employed is not limited to copper.

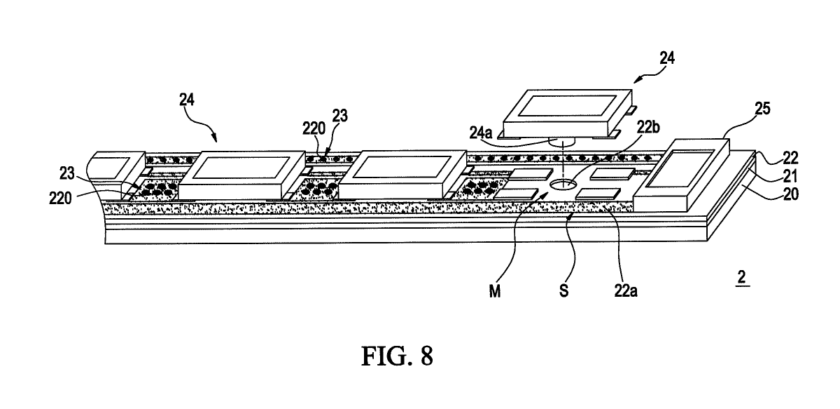

Referring to FIGS. 6, 7 and 8, FIG. 7 is a fourth illustration of the manufacturing method of the circuit board structure according to an embodiment of the present invention; and FIG. 8 is a perspective view of the circuit board structure according to an embodiment of the present invention.

The manufacturing method of the circuit board structure further including steps of:

as shown in FIGS. 6 to 8, performing a procedure of exposure and etching on a surface S of the metal layer 22 to form a metal circuit 22a on the surface S; then forming an opening 22b on an electronic component installation area M of the metal circuit 22a for connecting the metal substrate 20; and installing a light emitting diode module 24 on the electronic component installation area M by surface mount technology (SMT). A heat dissipation element 24a of the light emitting diode module 24 can be in direct contact with the metal substrate 20 through the opening 22b.

In the (step S120) of performing a procedure for connecting metal in the grooves 23 so that the metal substrate 20 and the metal layer 22 are in contact with each other, as shown in FIGS. 8, 5 and 6, a metal connecting procedure such as plating of a metal 220 (e.g. copper plating) can be further performed in the grooves 23 so that the metal substrate 20 and the metal layer 22 are in contact with each other, therefore a heat conduction coefficient and an overall heat dissipation efficiency of a circuit board structure 2 can be enhanced.

Accordingly, the heat energy generated by the electrically connected and irradiated light emitting diode module 24 can be transferred directly from the metal layer 22 to the metal substrate 20 through the metal 220 to have the heat dissipated speedily; furthermore, the heat energy of the heat dissipation element 24a of the light emitting diode module 24 can also be transferred directly to the metal substrate 20 through the opening 22b connected to the metal substrate 20 to have the heat dissipated speedily.

As shown in FIG. 8, the circuit board structure 2 of the present invention comprises the metal substrate 20, the dielectric layer 21 and the metal layer 22. The dielectric layer 21 is formed on the metal substrate 20, and the metal layer 22 is formed on the dielectric layer 21. The metal substrate 20 and the metal layer 22 can be in contact with each other at an appropriate position (e.g. the groove 23) by performing a metal connecting procedure.

More specifically, the metal circuit 22a is disposed on the surface S of the metal layer 22, the electronic component installation area M of the metal circuit 22a has the opening 22b for connecting to the metal substrate 20. One or a plurality of the light emitting diode modules 24 can be installed on the electronic component installation area M, and the heat dissipation element 24a of the light emitting diode module 24 can be in direct contact with the metal substrate 20 through the opening 22b. It should be noted that, the pattern of the metal circuit 22a shown in FIG. 8 is only for the purpose of comprehension and should not be construed as a limitation to the pattern of the circuit.

A connector 25 electrically connected to the metal circuit 22a is further disposed on the surface S of the metal layer 22. For example, the light emitting diode module 24 can be supplied with an external power source through the connector 25 so that an light emitting unit of the light emitting diode module 24 is irradiated. Nevertheless, a function of the connector 25 is not limited to it based on different requirements of circuit design. Furthermore, the dielectric layer 21 is formed between the metal substrate 20 and the metal layer 22 as an insulation layer. The metal substrate 20 includes an aluminum substrate and the metal layer 22 includes a copper layer; however, the metal substrate 20 and the metal layer 22 are not limited to be made of aluminum and copper, and other types of metal with different heat conduction coefficients can be employed based on different requirements of circuit design.

Accordingly, when the present invention is being used, the metal circuit 22a on the surface S of the metal layer 22 can be supplied with electricity through the connector 25, so that the light emitting diode module 24 on the circuit board structure 2 is supplied with electricity to irradiate. The heat energy generated by the electrically connected and irradiated light emitting diode module 24 can be transferred directly from the metal layer 22 to the metal substrate 20 through the metal 220 (e.g. silver or copper, etc.) to have the heat dissipated speedily; furthermore, the heat energy of the heat dissipation element 24a of the light emitting diode module 24 can also be transferred directly to the metal substrate 20 through the opening 22b connected to the metal substrate 20 to have the heat dissipated speedily.

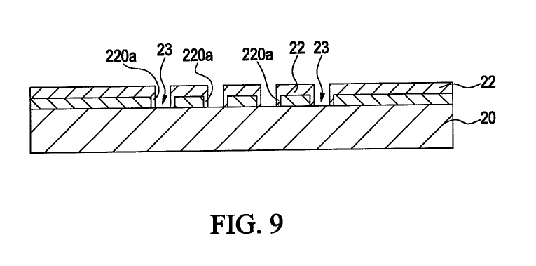

Referring FIG. 9, which is an illustration of the manufacturing method of the circuit board structure in FIG. 6 according to another embodiment of the present invention.

As shown in FIGS. 3 and 9, in the (step S120) of performing a procedure for connecting metal in the grooves so that the metal substrate and the metal layer are in contact with each other, a metal connecting procedure such as plating of a metal 220a (e.g. copper plating) can be performed in the grooves 23 so that the metal substrate 20 and the metal layer 22 are in contact with each other, therefore a heat conduction coefficient and an overall heat dissipation efficiency of the circuit board can be enhanced. In this embodiment, the grooves 23 are filled partially with a metal 220a, and the metal substrate 20 and the metal layer 22 can still be in contact with each other, and thus less material is used.

Accordingly, the circuit board structure and method for manufacturing the same of the present invention have the following advantages:

1. Having the metal substrate and the metal layer in contact with each other at an appropriate position (e.g. the groove), therefore a heat conduction coefficient and a heat dissipation efficiency of the circuit board can be enhanced.

2. The heat energy of the heat dissipation element of the light emitting diode module can also be transferred directly to the metal substrate through the opening connected to the metal substrate to have the heat dissipated speedily.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A manufacturing method of a circuit board structure, wherein including:
providing a circuit board which comprising a metal substrate, a metal layer and a dielectric layer disposed between the metal substrate and the metal layer;
forming a groove on the circuit board to expose the metal substrate, the dielectric layer and the metal layer; and
performing a procedure for connecting metal in the groove so that the metal substrate and the metal layer being in contact with each other.

2. The manufacturing method of the circuit board structure of claim 1, wherein further including:
performing a procedure of exposure and etching on a surface of the metal layer to form a metal circuit on the surface.

3. The manufacturing method of the circuit board structure of claim 2, wherein further including:
forming an opening on an electronic component installation area of the metal circuit for connecting the metal substrate.

4. The manufacturing method of the circuit board structure of claim 3, wherein further including:
installing a light emitting diode module on the electronic component installation area by surface mount technology (SMT), wherein a heat dissipation element of the light emitting diode module is in contact with the metal substrate through the opening.

5. A circuit board structure, wherein comprising:
a metal substrate;
a dielectric layer formed on the metal substrate; and
a metal layer formed on the dielectric layer;
wherein the metal substrate and the metal layer are in contact with each other at a position by performing a metal connecting procedure.

6. The circuit board structure of claim 5, wherein further comprising:
a metal circuit is disposed on a surface of the metal layer, an electronic component installation area of the metal circuit having an opening for connecting to the metal substrate.

7. The circuit board structure of claim 6, wherein further comprising:
a light emitting diode module is installed on the electronic component installation area, wherein a heat dissipation element of the light emitting diode module is in contact with the metal substrate through the opening.

8. The circuit board structure of claim 6, wherein a connector is further disposed on the surface of the metal layer to be electrically connected with the metal circuit.

9. The circuit board structure of claim 5, wherein the metal substrate includes an aluminum substrate.

10. The circuit board structure of claim 5, wherein the metal layer includes a copper layer.
